(19) United States
(12) Patent Application Publication
(10) Pub. No.: US 2015/0371970 A1
(43) Pub. Date: Dec. 24, 2015

(54) SEMICONDUCTOR DEVICE AND METHOD FOR MANUFACTURING THE SAME

(71) Applicant: PS4 Luxco S.a.r.l., Luxembourgh (LU)

(72) Inventor: Shinichio Sakurada, Tokyo (JP)

(21) Appl. No.: 14/435,452

(22) PCT Filed: Sep. 24, 2013
(86) PCT No.: PCT/JP2013/075645

§ 371 Date: Apr. 13, 2015

(30) Foreign Application Priority Data
Oct. 2, 2012 (JP) 2012-220197

(51) Int. Cl. H01L 25/065; H01L 21/268; H01L 23/48; H01L 23/498; H01L 21/78; H01L 23/00

(52) U.S. Cl. CPC H01L 25/0657; H01L 21/78; H01L 24/17; H01L 23/481; H01L 24/11; H01L 23/49838; H01L 23/564; H01L 21/268; H01L 2225/06513; H01L 2225/06517; H01L 2225/06541; H01L 2224/16146; H01L 2224/16225

(57) ABSTRACT

In the present invention, a semiconductor wafer is prepared, said semiconductor wafer having a plurality of semiconductor chip regions, each of which is to be a semiconductor chip having a desired circuit formed on one surface, and cutting regions that are provided among the semiconductor chip regions. A modified layer is formed along the outer circumference of each of the semiconductor chip regions in each of the semiconductor chip regions, said modified layer reaching, from at least the inner portion of the semiconductor wafer, the other surface where no circuit is to be formed. Then, the semiconductor wafer is divided into a plurality of semiconductor chips by cutting the semiconductor wafer at the cutting regions.

### TECHNICAL FIELD

The present invention relates to a semiconductor device and a method for manufacturing the same.

### BACKGROUND ART

In recent years the size of circuits in semiconductor devices has tended to increase as the level of functionality of electronic equipment has increased. However, because electronic equipment is becoming more compact and thinner, there is a desire for techniques that allow semiconductor devices to become more compact while being equipped with more circuits. One such technique is a CoC (Chip on Chip)-type semiconductor device in which a plurality of semiconductor chips having through-electrodes are stacked on one another. The structure and method of manufacture of such a CoC-type semiconductor device are for example described in patent literature article 1.

In a CoC-type semiconductor device, a plurality of bump electrodes connected to through-electrodes are formed respectively on both surfaces of each semiconductor chip to connect the semiconductor chips to a wiring board on which prescribed wiring lines have been formed, or to connect pairs of the plurality of stacked semiconductor chips to each other.

However, in the process of manufacturing a semiconductor device, a plurality of semiconductor chip regions provided with desired circuits are formed on a semiconductor wafer, after which the periphery of said semiconductor chip regions is cut using a dicing blade or the like to separate the semiconductor wafer into individual semiconductor chips. At this time, in order to hold the semiconductor chips after separation, a protecting tape (dicing tape) is bonded in advance to the surface (the reverse surface) on the opposite side to the surface from which the dicing blade begins to cut. A UV tape, in which the bonding strength of an adhesive layer is reduced when irradiated with ultraviolet light or the like, is for example used as the dicing tape. After the semiconductor wafer has been cut, the bonding strength of the adhesive layer of the dicing tape is reduced, after which each individual semiconductor chip is picked up and supplied to equipment for packaging.

Here, when the dicing tape is bonded to the semiconductor wafer on which the bump electrodes described above have been formed, the dicing tape must be affixed in such a way that the bump electrodes are embedded in the adhesive layer of the dicing tape. The adhesive layer of the dicing tape which is bonded to the surface of the semiconductor wafer on which the bump electrodes have been formed must therefore be thick.

However, making the adhesive layer of the dicing tape thick causes problems in that the semiconductor wafer secured using the relatively soft adhesive layer moves slightly when said semiconductor wafer is cut by the rapidly-rotating dicing blade, and the reverse surface (the surface to which the dicing tape has been bonded) side in the location that has been cut comes into contact with the dicing blade, causing chipping of the semiconductor chip after separation.

Chipping is a problem that occurs even if dicing is performed using dicing tape that is not provided with a thick adhesive layer, and is difficult to eliminate completely. It is therefore critical to suppress the amount of chipping (the chipped width in a direction orthogonal to the cutting direction) to within a predetermined nominal value. If the amount of chipping is large, the strength (flexural strength) of the semiconductor chip deteriorates, causing the reliability of the semiconductor device to deteriorate. In particular, it is desirable for the amount of chipping to be reduced further if the semiconductor wafer is thin. Further, if bump electrodes are disposed in the vicinity of the periphery of the semiconductor chip, there is even a risk that said bump electrodes will be lost if the amount of chipping is large.

It should be noted that stealth dicing techniques that employ laser light are known as methods for cutting a thin semiconductor wafer relatively satisfactorily. Patent literature article 2, for example, describes a stealth dicing technique.

Patent literature article 2 describes a method in which a semiconductor wafer is irradiated with laser light having a characteristic that allows it to pass through said semiconductor wafer, the focal point of the laser light being made to coincide with the interior of the semiconductor wafer, thereby forming modified layers (optically damaged portions) in the interior of said semiconductor wafer along a preset cutting line, after which a stretchable tape which has been bonded to the surface on the side opposite to the surface irradiated with the laser light is stretched, thereby cutting (cutting by pulling) the semiconductor wafer, with the abovementioned modified layers serving as starting points.

### PATENT LITERATURE

Japanese Patent Kokai 2010-251347
Japanese Patent Kokai 2005-340423

### SUMMARY OF THE INVENTION

### Problems to be Resolved by the Invention

With a dicing technique such as that described above in which the semiconductor wafer is cut using a rapidly-rotating dicing blade, the semiconductor chip becomes chipped after separation, and if the amount of chipping is large there is a risk that the flexural strength of the semiconductor chip will deteriorate, causing the reliability of the semiconductor device to deteriorate. Further, if bump electrodes are disposed in the vicinity of the periphery of the semiconductor chip, there is even a risk that said bump electrodes will be lost if the amount of chipping is large.

### Means of Overcoming the Problems

One mode of embodiment of the semiconductor device of this application comprises a wiring board, and

a semiconductor chip mounted on the wiring board,
wherein,
the semiconductor chip is provided with
a modified layer which is formed along an outer periphery and which reaches at least from the interior to a surface on which a circuit is not formed.

Meanwhile, one mode of embodiment of the method of manufacturing a semiconductor device in this application comprises: a step of preparing a semiconductor wafer having a plurality of semiconductor chip regions, on one surface of which desired circuits are formed, and cutting regions provided between the plurality of semiconductor chip regions;

a step of forming modified layers in the semiconductor chip regions, along an outer periphery of said semiconductor chip regions, and reaching at least from the interior to another surface, on which the circuits are not formed; and
a step of separating each of the plurality of semiconductor chip regions by cutting the semiconductor wafer in the cutting regions.

In the configuration and method described above, by forming modified layers along the outer periphery of the semiconductor chip regions, even if cracks are generated as a result of chipping when the semiconductor wafer is cut, the progress of said cracks is stopped by the modified layers. The amount of chipping can therefore be controlled by means of the position in which the modified layers are formed, and by forming the modified layers in such a way that the amount of chipping is equal to or less than a prescribed nominal value, the amount of chipping that occurs on the side surfaces of the semiconductor chip during cutting can be reduced.

### Advantages of the Invention

According to the present invention, the amount of chipping that occurs when the semiconductor chips are separated from the semiconductor wafer can be reduced, and therefore the flexural strength of the semiconductor chip can be maintained satisfactorily and the reliability of the semiconductor device can be improved.

### BRIEF EXPLANATION OF THE DRAWINGS

FIG. 1 is a cross-sectional view illustrating a configuration example of a semiconductor device according to a first mode of embodiment.

FIG. 2 are plan views illustrating configuration examples of a semiconductor chip with which the semiconductor device illustrated in FIG. 1 is provided.

FIG. 3 is a cross-sectional view illustrating an example of a procedure for manufacturing the semiconductor chip illustrated in FIG. 2.

FIG. 4 is a cross-sectional view illustrating an example of a procedure for manufacturing the semiconductor chip illustrated in FIG. 2.

FIG. 5 is a cross-sectional view illustrating an example of a procedure for assembling the chip stack illustrated in FIG. 1.

FIG. 6 is a cross-sectional view illustrating an example of a procedure for assembling the semiconductor device illustrated in FIG. 1.

FIG. 7 is a cross-sectional view illustrating a configuration example of a semiconductor device according to a second mode of embodiment.

FIG. 8 is a cross-sectional view illustrating a configuration example of a semiconductor device according to a third mode of embodiment.

FIG. 9 is a cross-sectional view illustrating a modified example of a semiconductor device according to the present invention.

### MODES OF EMBODYING THE INVENTION

The present invention will next be described with reference to the drawings.

### First Mode of Embodiment

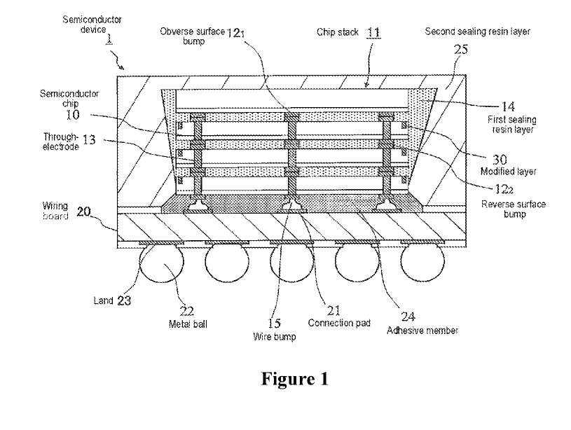

FIG. 1 is a cross-sectional view illustrating a configuration example of a semiconductor device according to a first mode of embodiment. FIG. 1 illustrates a configuration example of a CoC-type semiconductor device.

As illustrated in FIG. 1, a semiconductor device 1 according to the first mode of embodiment has a chip stack 11 in which a plurality of semiconductor chips 10 are stacked on one other, the configuration being such that said chip stack 11 is connected and fixed to a wiring board 20 on which prescribed wiring lines are formed. The chip stack 11 is formed from a plurality (four, in FIG. 1) of memory chips (semiconductor chips) 10 on which memory circuits are formed, for example.

The semiconductor chips 10 are each provided with a plurality of bump electrodes, on one surface (the obverse surface) on which the circuits are formed, and on the other surface (the reverse surface) on which the circuits are not formed, and the bump electrodes (obverse surface bumps) 12₁ on the one surface are respectively connected to the bump electrodes (reverse surface bumps) 12₂ on the other surface by way of through-wiring 13. The semiconductor chips 10 are connected to each other by means of the through-electrodes 13, by way of the obverse surface bumps 12₁ and the reverse surface bumps 12₂. However, in the semiconductor device 1 according to this mode of embodiment, reverse surface bumps 12₂ and through-electrodes 13 are not formed on/in the uppermost semiconductor chip 10 (the semiconductor chip 10 furthest away from the wiring board 20) in the chip stack 11 comprising the plurality of semiconductor chips 10, only obverse surface bumps 12₁ being formed thereon.

The chip stack 11 is provided with a first sealing resin layer 14 which fills the gaps between the semiconductor chips 10 and which has a substantially trapezoidal cross-section as seen from the side surface. The first sealing resin layer 14 is formed using a known underfill material or the like.

The semiconductor chip 10 disposed at the short side (upper bottom) of the substantially trapezoidal first sealing resin layer 14, in the chip stack 11, is connected and fixed to the wiring board 20. A glass epoxy board on both sides of which prescribed wiring lines have been formed is used, for example, as the wiring board 20, and each wiring line, except for connection pads and lands, is covered by an insulating film such as a solder resist film.

A plurality of connection pads 21 for connecting to the chip stack 11 are formed on one surface of the wiring board 20, and a plurality of lands 23 for connecting and fixing metal balls 22, which serve as external terminals, are formed on the other surface.

Wire bumps 15 comprising Au, Cu or the like are formed on the connection pads 21 of the wiring board 20, and said wire bumps 15 are connected to the plurality of obverse surface bumps 12₁ on the semiconductor chip 10 disposed at the short side (upper bottom) of the substantially trapezoidal first sealing resin layer 14. Further, the chip stack 11 and the wiring board 20 are adhesively fixed by means of an adhesive member 24 such as an NCP (Non Conductive Paste), and the locations of the joints between the wire bumps 15 and the obverse surface bumps 12₁ on the semiconductor chip 10 are protected by said adhesive member 24.

The chip stack 11 on the wiring board 20 is sealed by means of a second sealing resin layer 25, and the metal balls 22 which serve as external terminals of the semiconductor device 1 are connected to each of the plurality of lands 23 on the other surface of the wiring board 20, on which the chip stack 11 is not mounted.

It should be noted that, as discussed hereinabove, in the semiconductor device 1 according to this mode of embodiment, reverse surface bumps 12₂ and through-electrodes 13 are not formed on/in the uppermost semiconductor chip 10 in the chip stack 11, only obverse surface bumps 12₁ being formed thereon. With such a configuration in which a semiconductor chip 10 having no through-electrodes 13 is provided on the uppermost level, even if stresses are generated in the semiconductor chips 10 as a result of expansion or contraction of the through-electrodes 13 caused by temperature changes during the manufacturing process, said stresses are accepted by the obverse surface of the uppermost semiconductor chip 10 and are thus dispersed. Further, in the uppermost semiconductor chip 10, because there are no through-electrodes 13, stresses accepted from the opposing semiconductor chip 10 (in FIG. 1, the third semiconductor chip 10 away from the wiring board 20) are more readily dispersed by means of the whole substrate. The generation of cracks in the semiconductor chips 10 that occurs as a result of temperature changes during the manufacturing process can therefore be suppressed.

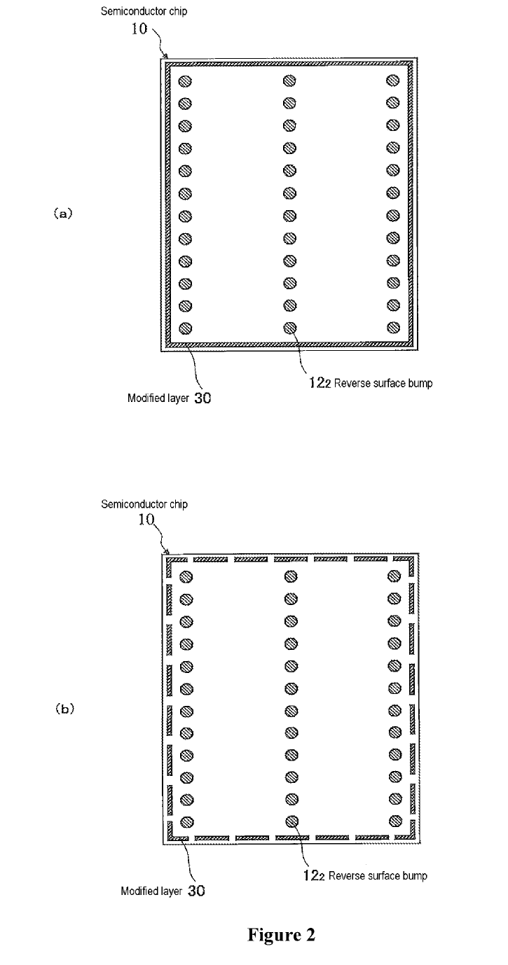

FIG. 2 are plan views illustrating configuration examples of a semiconductor chip with which the semiconductor device illustrated in FIG. 1 is provided. FIGS. 2 (a) and (b) illustrate configuration examples of the reverse surface of the semiconductor chips 10 (excluding the uppermost semiconductor chip 10 described above) illustrated in FIG. 1.

As illustrated in FIG. 2 (a), the semiconductor chip 10 in this mode of embodiment has a configuration in which modified layers 30 reaching from the interior to the reverse surface (the other surface, on which circuits are not formed) are formed along the side surfaces (the outer periphery of the semiconductor chip 10), positioned a slight distance away from said side surfaces.

The modified layers 30 are optically damaged portions formed in the interior of the semiconductor wafer 10 by irradiating the semiconductor wafer 10 with laser light, and they can for example be obtained using the stealth dicing technique described hereinabove. The modified layers 30 are described in detail in patent literature article 2 discussed hereinabove, for example. The modified layers 30 are formed in a position that is approximately a few μm inward of the side surfaces of the semiconductor chip 10, for example in a position that is approximately 5 μm from the side surfaces. However, in the semiconductor device 1 in the first mode of embodiment, modified layers 30 are not formed in the uppermost semiconductor chip 10 in the chip stack 11 comprising the plurality of semiconductor chips 10.

If the modified layers 30 are formed along the outer periphery of the semiconductor chip 10 in this way, even if cracks are generated as a result of chipping on the reverse surface side of said semiconductor chip 10 when the semiconductor wafer is cut using a dicing blade, the progress of said cracks is stopped by the modified layers 30. The amount of chipping can therefore be controlled by means of the position in which the modified layers 30 are formed, and by forming the modified layers 30 in such a way that the amount of chipping is equal to or less than a prescribed nominal value, the amount of chipping that occurs on the side surfaces of the semiconductor chip 10 during cutting can be reduced. Therefore, even if a relatively thin semiconductor wafer having a thickness of approximately 50 μm, for example, is cut, the flexural strength of the semiconductor chip 10 after cutting can be maintained satisfactorily and the reliability of the semiconductor device 1 can be improved. Further, because the amount of chipping can be reduced, in cases in which bump electrodes are disposed at the periphery of the semiconductor chip 10, loss of said bump electrodes can be prevented.

It should be noted that although FIG. 2 (a) illustrates an example in which the modified layers 30 are formed continuously (in the form of straight lines) along the outer periphery of the semiconductor chip 10, it is sufficient for the modified layers 30 to be formed along the outer periphery of the semiconductor chip 10, and they may also be formed in the form of dashed lines as illustrated in FIG. 2 (b), for example. Further, the shape of the modified layers 30 is not limited to being the straight-line shape illustrated in FIG. 2 (a) or the dashed-line shape illustrated in FIG. 2(b), and they may be formed in various line shapes, for example alternate long and short dashed lines, or alternate long and two short dashed lines, and the modified layers 30 formed with these line shapes may have a certain amount of width.

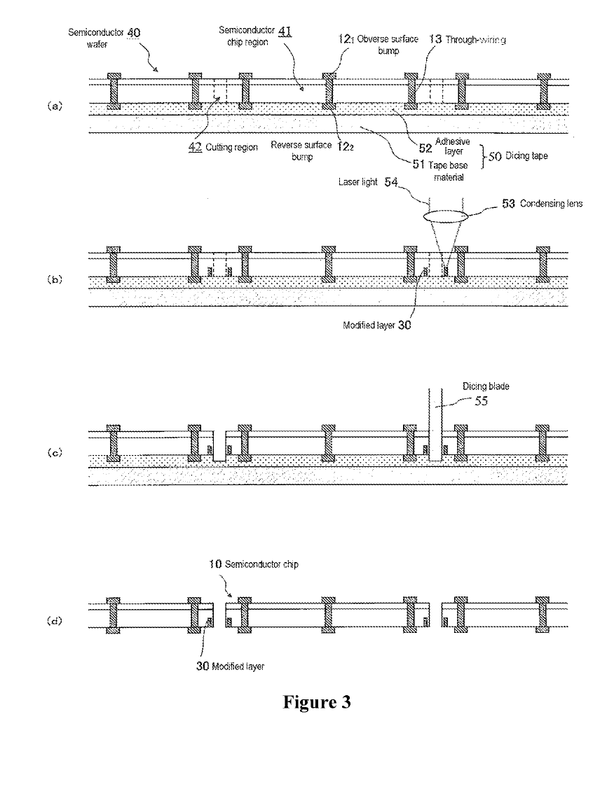

A method of manufacturing the semiconductor chip 10 and the chip stack 11 provided in the semiconductor device according to the first mode of embodiment illustrated in FIG. 1 will now be described with reference to FIG. 3 to FIG. 5.

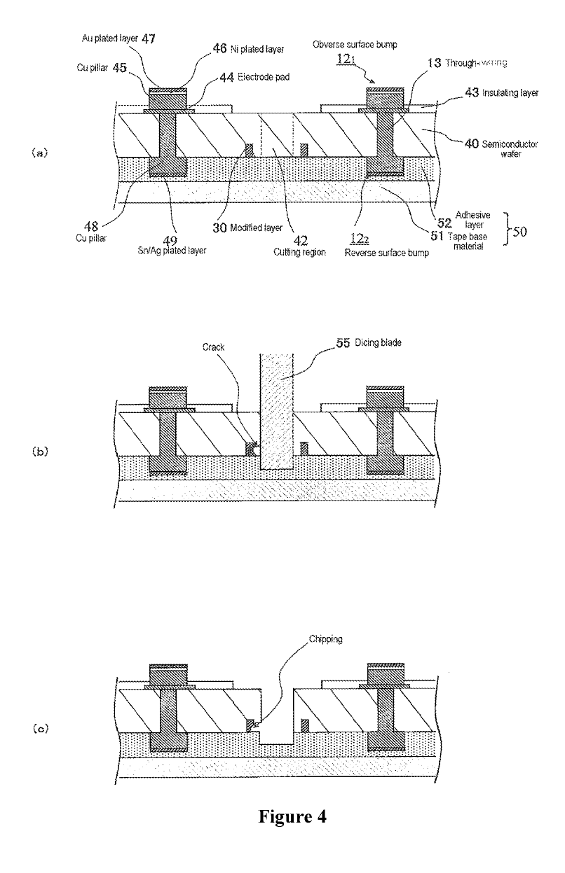

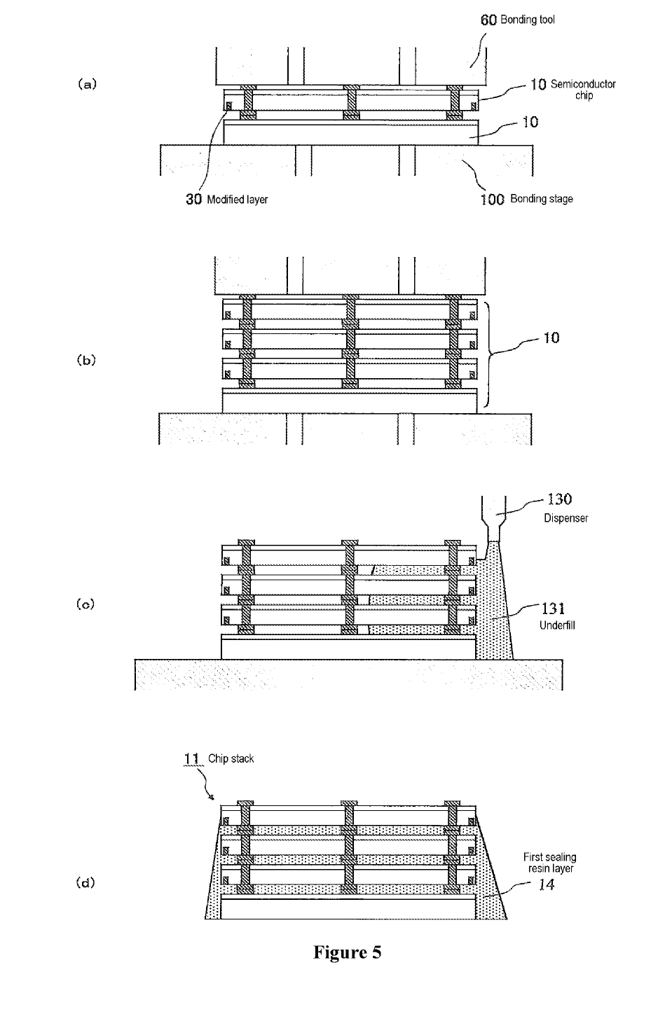

FIG. 3 (a) to (d) and FIG. 4 (a) to (c) illustrate an example of a procedure for manufacturing the semiconductor chip 10 illustrated in FIG. 2, and FIG. 5 (a) to (d) illustrate an example of a procedure for assembling the chip stack 11 illustrated in FIG. 1.

When manufacturing the semiconductor chip 10 illustrated in FIG. 1, a semiconductor wafer 40, comprising a plurality of semiconductor chip regions 41 on one surface of which desired circuits, for example memory circuits, are formed, is prepared. Cutting regions 42, which are regions that are cut in a dicing step, are provided between the semiconductor chip regions 41 of the semiconductor wafer 40.

A plurality of obverse surface bumps 12₁ are formed on one surface (the obverse surface) of the semiconductor chip regions 41, a plurality of reverse surface bumps 12₂ are formed on the other surface (the reverse surface), and each obverse surface bump 12₁ is connected to a corresponding reverse surface bump 12₂ by way of a through-electrode 13.

As illustrated in FIG. 4 (a), for example, the obverse surface bumps 12₁ comprise a Cu pillar 45 formed on an electrode pad 44 exposed through an insulating layer 43, and an Ni plated layer 46 and an Au plated layer 47 formed on said Cu pillar 45. The reverse surface bumps 12₂ comprise, for example, a Cu pillar 48 connected to the through-electrode 13, and an Sg/Ag plated layer 49 formed on said Cu pillar 48.

As illustrated in FIG. 3 (a) and FIG. 4 (a), in the process of manufacturing the semiconductor chip 10, first a dicing tape 50 is bonded and fixed to the reverse surface of the semiconductor wafer 40 discussed hereinabove. The dicing tape 50 comprises a tape base material 51 and an adhesive layer 52, and is bonded in such a way that the reverse surface bumps 12₂ of the semiconductor wafer 40 are embedded in said adhesive layer 52.

Next, as illustrated in FIG. 3 (b) and FIG. 4 (a), modified layers 30 reaching from the interior to the reverse surface of the semiconductor wafer 40 are formed along the outer periphery of the semiconductor chip regions 41, positioned within the semiconductor chip regions 41, a slight distance away from the cutting regions 42 of the semiconductor wafer 40. As discussed hereinabove, the modified layers 30 should be formed by focusing and radiating laser light 54 at a prescribed position in the interior of the semiconductor chip region 41 using a condensing lens 53, by means of a known stealth dicing technique, for example. The modified layers 30 are formed along the outer periphery of the semiconductor chip regions 41, in positions that are approximately a few μm from the cutting regions 42, for example in positions that are approximately 5 μm inward from the end portions of said semiconductor chip regions 41. It should be noted that the positions in which the modified layers 30 are formed is not restricted to being approximately 5 μm inward from the end portions of the semiconductor chip regions 41, and should be set appropriately in accordance with the nominal value of the amount of chipping.

As illustrated in FIG. 3 (c), the semiconductor wafer 40 in which the modified layers 30 have been formed for each semiconductor chip region 41 is cut (full cut) at the cutting regions 42 using a dicing blade 55 provided in a dicing device, which is not shown in the drawings, thereby separating the semiconductor wafer 40 into individual semiconductor chips 10. Here, because the adhesive layer 52 of the dicing tape 50 is formed having a thickness such that it embeds the reverse surface bumps 12₂ of the semiconductor wafer 40, the semiconductor wafer 40 which is fixed using the relatively soft adhesive layer 52 is liable to move slightly when said semiconductor wafer 40 is cut. The reverse surfaces of the semiconductor chip regions 41 therefore come into contact with the dicing blade 55, and chipping occurs on the side surfaces of the semiconductor chips 10 after cutting, in particular on the reverse surface side.

However, in the semiconductor device according to the first mode of embodiment, by providing the modified layers 30 formed along the outer periphery of the semiconductor chip regions 41, even if the end portions of the semiconductor chip regions 41 come into contact with the dicing blade 55 and cracks are generated as a result of chipping on the reverse surface side, the progress of said cracks is stopped by the modified layers 30, as illustrated in FIG. 4 (b), and chipping occurs along the modified layers 30 as illustrated in FIG. 4 (c). The amount of chipping can therefore be controlled by means of the positions in which the modified layers 30 are formed, and by forming the modified layers 30 in positions within the semiconductor chip regions 41 of the semiconductor wafer 40, a slight distance from the cutting regions 42, the amount of chipping can be reduced.

Because the amount of chipping can be reduced, deteriorations in the flexural strength of the semiconductor chip 10 can be suppressed and the reliability of the semiconductor chip can be maintained. Further, because the amount of chipping can be reduced, in cases in which bump electrodes are disposed at the periphery of the semiconductor chip 10, loss of said bump electrodes can be prevented.

After the semiconductor wafer 40 has been cut, the bonding strength of the adhesive layer 52 of the dicing tape 50 is reduced, for example by irradiating the dicing tape 50 with ultraviolet light, after which semiconductor chips 30 having modified layers 30 formed along the outer periphery, as illustrated in FIG. 3 (d), are obtained by picking up the dicing tape 50.

With the stealth dicing technique described in patent literature article 2 discussed hereinabove, the individual semiconductor chips are separated and cut, with the modified layers serving as starting points, by stretching a stretchable dicing tape which has been bonded to the semiconductor wafer. In this method, if the amount of extension of the dicing tape differs depending on the location, there is a risk that it will not be possible for the semiconductor chips to be satisfactorily separated, for example in peripheral regions of the dicing tape in which the amount of extension is small. Further, in locations in which the amount of extension is small, the gaps between pairs of semiconductor chips is small, and there is a risk that it will not be possible for individual semiconductor chips to be picked up satisfactorily. However, in the method of manufacturing the semiconductor device according to this mode of embodiment, the semiconductor wafer 40 is cut using the dicing blade 55, and therefore a gap corresponding to the width of the cutting region 42 is maintained between the semiconductor chips 10 after cutting. The semiconductor chips 10 after cutting can therefore be picked up satisfactorily.

The semiconductor chips 10 after cutting are picked up individually using a known bonding tool 60, and are placed on a bonding stage 100, illustrated in FIG. 5 (a), with the surface on which the prescribed circuits are formed facing upward.

As illustrated in FIG. 5 (a), a second-level semiconductor chip 10 is mounted on a first-level semiconductor chip 10 which is held on the bonding stage 100, and the second-level semiconductor chip 10 is connected and fixed onto the first-level semiconductor chip 10 by joining the obverse surface bumps 12₁ of the first-level semiconductor chip 10 to the reverse surface bumps 12₂ of the second-level semiconductor chip 10.

A thermocompression bonding method, in which a prescribed load is applied to the semiconductor chip 10 by the bonding tool 60, which is set to a high temperature (approximately 300° C.), should be used to join the obverse surface bumps 12₁ to the reverse surface bumps 12₂. Pairs of semiconductor chips 10 may be joined using not only a thermocompression bonding method, but also an ultrasonic bonding method, in which pressure is applied while ultrasonic waves are applied, or an ultrasonic thermo-compression bonding method in which these methods are combined.

A third-level semiconductor chip 10 is connected and fixed onto the second-level semiconductor chip 10 using the same procedure as that described hereinabove, and a fourth-level semiconductor chip 10 is connected and fixed onto the third-level semiconductor chip 10 using the same procedure as that described hereinabove (FIG. 5 (b)).

A chip stack 11 comprising the plurality of semiconductor chips 10 formed using the procedure described hereinabove is placed on a sheet for coating, not shown in the drawings, which is stuck to the stage, and as illustrated in FIG. 5 (c), an underfill material 131 is supplied using a dispenser 130 from the vicinity of the end portion of the chip stack 11. The supplied underfill material 131 enters gaps between pairs of semiconductor chips 10 by means of a capillary phenomenon, thereby filling the gaps between the semiconductor chips 10, while forming fillets at the periphery of the stacked plurality of semiconductor chips 10.

After the underfill material 131 has been supplied, the chip stack 11 is cured (heat treated) at a prescribed temperature, for example a temperature of approximately 150° C., thereby thermally curing the underfill material 131. As a result, a first sealing resin layer 14 comprising the underfill material 131 which fills the gaps between the semiconductor chips 10 and covers the periphery of the chip stack 11 is formed, as illustrated in FIG. 5 (d).

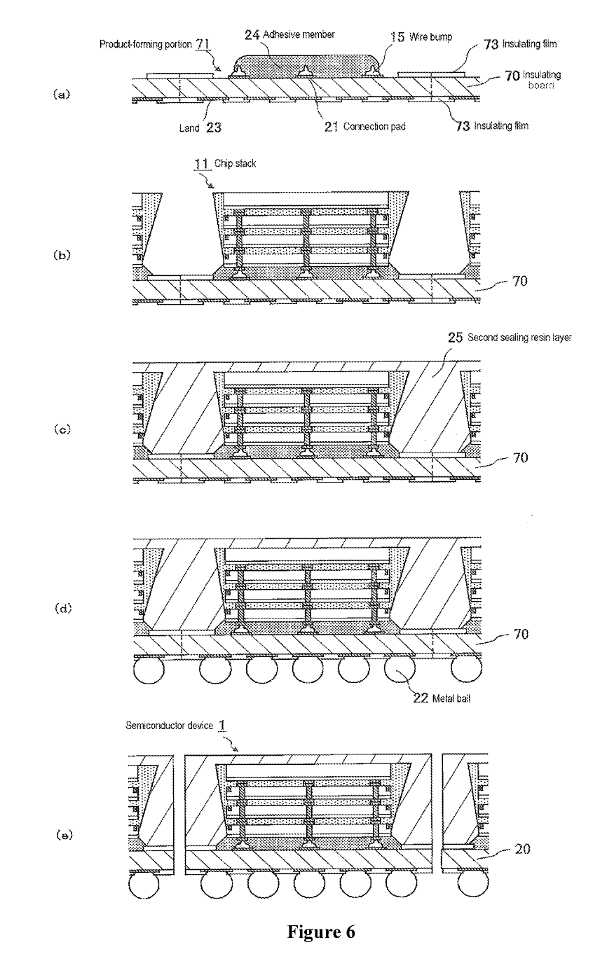

A procedure for assembling the semiconductor device 1 according to the first mode of embodiment will now be described with reference to FIG. 6.

FIG. 6 is a cross-sectional view illustrating an example of a procedure for assembling the semiconductor device illustrated in FIG. 1. It should be noted that FIG. 6 (a) to (e) illustrate an assembly procedure for forming a plurality of semiconductor devices 1 in one batch.

When assembling the semiconductor device 1, first an insulating board 70 provided with a plurality of product-forming portions 71 is prepared. The product-forming portions 71 are locations which will form the wiring boards 20 of each semiconductor device 1, a prescribed pattern of wiring lines is formed on each product-forming portion 71, and each wiring line, except for the connection pads 21 and the lands 23, is covered by an insulating film 73 such as a solder resist film. Spaces between the product-forming portions 71 of the insulating board 70 serve as dicing lines (dotted line portions) when the individual semiconductor devices 1 are cut apart.

A plurality of connection pads 21 for connecting to the chip stack 11 are formed on one surface of the product-forming portions 71 of the insulating board 70, and a plurality of lands 23 for connecting metal balls 22, which serve as external terminals, are formed on the other surface. These connection pads 21 are connected to prescribed lands 23 by way of wiring lines.

When preparation of the insulating board 70 is complete, wire bumps 15 are formed on the connection pads 21 of the product-forming portions 71, as illustrated in FIG. 6 (a).

The wire bumps 15 should be formed by joining a metal wire comprising Au, Cu or the like, the distal end of which has been melted to form it into a ball shape, onto the connection pad 21 by means of an ultrasonic thermo-compression bonding method or the like, and then cutting the wire by pulling it, using a wire bonding device, which is not shown in the drawings.

An insulating adhesive member 24 such as an NCP is then applied onto each product-forming portion 26 using a dispenser, which is not shown in the drawings.

Next, the chip stacks 11 are held by suction-attachment using a bonding tool or the like, which is not shown in the drawings, and are mounted respectively on the product-forming portions 26 of the insulating board 70 (FIG. 6 (b)), and the obverse surface bumps 12₁ of the lowermost semiconductor chip 10 (the semiconductor chip 10 disposed at the short side (the upper bottom) of the substantially trapezoidal first sealing resin layer 14) in each chip stack 11 are joined to the wire bumps 15 of the insulating board 70 using thermocompression bonding or the like. At this time, the adhesive member 24 applied to the insulating board 70 fills the spaces between the chip stacks 11 and the insulating board 70, adhesively fixing the insulating board 70 and the chip stacks 11 together.

The insulating board 70 on which the chip stacks 11 have been mounted is set, for example in a molding die comprising an upper die and a lower die of a transfer molding device, which is not shown in the drawings, and the procedure moves to a molding step.

A cavity, which is not shown in the drawings, collectively covering a plurality of chip stacks 11, is formed in the upper die of the molding die, and the chip stacks 11 mounted on the insulating board 70 are accommodated in said cavity.

Next, a sealing resin that has been melted by heating is injected into the cavity provided in the upper die of the molding die, and the cavity is filled with the sealing resin in such a way as to entirely cover the chip stacks 11. A thermosetting resin such as an epoxy resin is used as the sealing resin.

Then, in a state in which the cavity is filled with the sealing resin, the sealing resin is thermally cured by curing it at a prescribed temperature, for example approximately 180° C., to form a second sealing resin layer 25 which collectively covers the chip stacks 11 mounted on the plurality of product-forming portions 71, as illustrated in FIG. 6 (c). Further, the sealing resin (the second sealing resin layer 25) is completely cured by baking it at a prescribed temperature.

The procedure next moves to a metal ball mounting step, in which, as illustrated in FIG. 6 (d), the electrically conductive metal balls 22, such as solder balls, which serve as external terminals of the semiconductor device, are connected and fixed to the lands 23 formed on the other surface of the insulating board 70.

In the step of mounting the metal balls, the plurality of metal balls 22 should for example be held by suction-attachment using a mounting tool provided with a plurality of suction-attachment holes, the positions of which coincide with the positions of the lands 23 on the insulating board 70, and after transferring flux to the metal balls 22, the held metal balls 22 should be mounted in a batch onto the lands 23 of the insulating board 70.

After metal balls 22 have been mounted onto all of the product-forming portions 71, the insulating board 70 is subjected to reflow to connect the metal balls 22 to the lands 23.

When connection of the metal balls 22 is complete, the procedure moves to a board dicing step in which the individual product-forming portions 71 are separated by cutting along prescribed dicing lines, thereby forming the semiconductor devices 1 in which the chip stacks 11 are mounted on the wiring boards 20.

In the board dicing step, the product-forming portions 71 are supported by bonding a dicing tape to the second sealing resin layer 25. The product-forming portions 71 are then separated by cutting the prescribed dicing lines using a dicing blade provided in a dicing device, which is not shown in the drawings, as illustrated in FIG. 6 (e). After separation by cutting, the CoC-type semiconductor device 1 illustrated in FIG. 1 is obtained by peeling the dicing tape from the product-forming portion 71.

According to the first mode of embodiment, by providing the modified layers 30, which are formed along the outer periphery of the semiconductor chip 10, even if cracks are generated as a result of chipping on the reverse surface side of the semiconductor chip 10 when the semiconductor wafer 40 is cut using a dicing blade, the progress of said cracks is stopped by the modified layers 30. The amount of chipping can therefore be controlled by means of the position in which the modified layers 30 are formed, and by forming the modified layers 30 in such a way that the amount of chipping is equal to or less than a prescribed nominal value, the amount of chipping that occurs on the side surfaces of the semiconductor chip 10 during cutting can be reduced.

Therefore the flexural strength of the semiconductor chip 10 after cutting can be maintained satisfactorily and the reliability of the semiconductor device 1 can be improved. Further, because the amount of chipping can be reduced, in cases in which bump electrodes are disposed at the periphery of the semiconductor chip 10, loss of said bump electrodes can be prevented.

### Second Mode of Embodiment

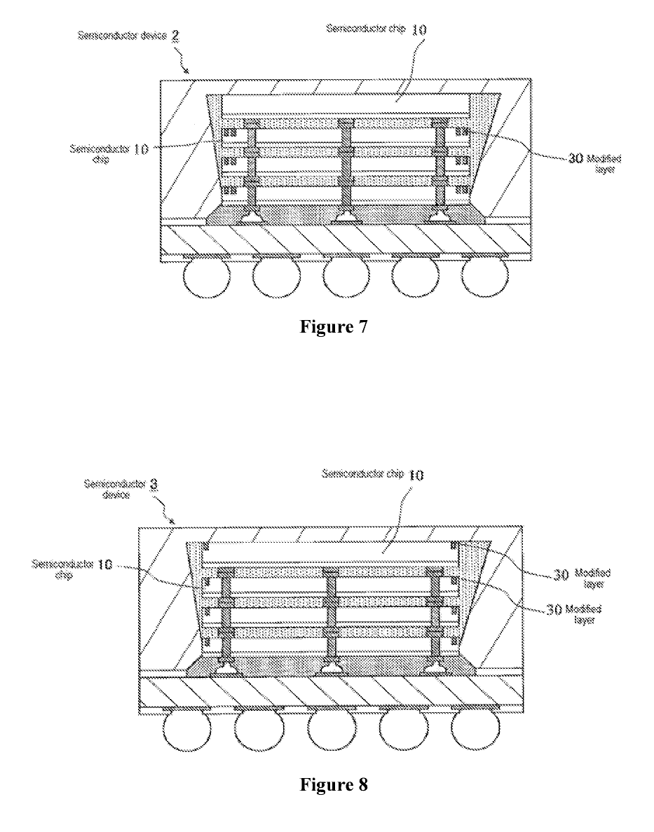

FIG. 7 is a cross-sectional view illustrating a configuration example of a semiconductor device according to a second mode of embodiment.

As illustrated in FIG. 7, a semiconductor device 2 according to the second mode of embodiment differs from the first mode of embodiment in that the modified layers 30 are formed in duplicate along the outer periphery of the semiconductor chip 10. Other aspects of the configuration of the semiconductor device 2 and the method of manufacture thereof are the same as in the semiconductor device 1 according to the first mode of embodiment, and descriptions thereof are therefore omitted.

The same effects as in the first mode of embodiment can be obtained with the semiconductor device 2 according to the second mode of embodiment, and by forming the modified layers 30 in duplicate, the risk that the amount of chipping will increase can be reduced even more than in the first mode of embodiment.

### Third Mode of Embodiment

FIG. 8 is a cross-sectional view illustrating a configuration example of a semiconductor device according to a third mode of embodiment.

As illustrated in FIG. 8, a semiconductor device 3 according to the third mode of embodiment differs from the first mode of embodiment in that modified layers 30 are also formed in the semiconductor chip 10 disposed on the uppermost level, on which reverse surface bumps 12₂ and through-electrodes 13 are not formed. Other aspects of the configuration of the semiconductor device 3 and the method of manufacture thereof are the same as in the semiconductor device 1 according to the first mode of embodiment, and descriptions thereof are therefore omitted.

The dicing technique illustrated in the first mode of embodiment, in which modified layers 30 are formed along the outer periphery of the semiconductor chip 10 and cutting is performed using a dicing blade, can also be applied to semiconductor chips 10 on which reverse surface bumps 12₂ are not formed. Chipping occurs on the side surfaces of the semiconductor chips 10 after separation, even in cases in which dicing tape 50 provided with an adhesive layer 52 that is thinner than in the first mode of embodiment is bonded to the reverse surface of the semiconductor wafer 40, and the individual semiconductor chips 10 are separated by cutting using a dicing blade. The semiconductor chip 10 created by applying the method of manufacture according to the present invention also acts effectively in reducing the amount of chipping, even if dicing tape 50 provided with such a thin adhesive layer 52 is used.

The same effects as in the first mode of embodiment can be obtained with the semiconductor device 3 according to the third mode of embodiment, and the amount of chipping of the semiconductor chip 10 which has no reverse surface bumps 12₂, disposed at the uppermost level, can also be reduced.

It should be noted that the present invention is not restricted to the configurations and methods illustrated in the first mode of embodiment to the third mode of embodiment, and various modifications are possible without deviating from the gist of the invention.

For example, in the first mode of embodiment to the third mode of embodiment, a CoC-type semiconductor device in which a chip stack 11 comprising a plurality of semiconductor chips 10 stacked on each other is mounted on a wiring board 20 is described by way of example, and descriptions are given of methods of manufacturing the semiconductor chips 10 with which said semiconductor device is provided, but the semiconductor chips 10 created by applying the method of manufacture according to the present invention can be mounted in any type of semiconductor device.

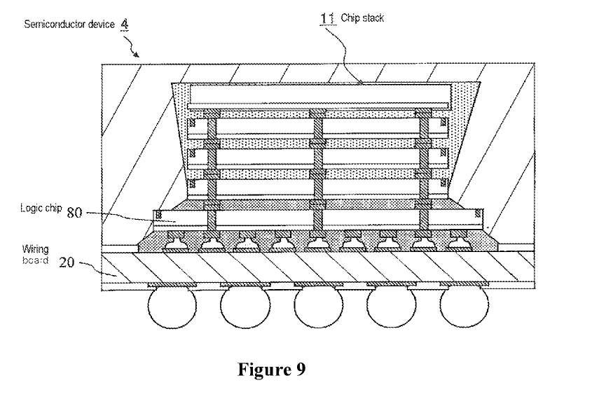

Further, the descriptions in the first mode of embodiment to the third mode of embodiment use examples in which the chip stack 11 is mounted directly on the wiring board 20, but, as in the semiconductor device 4 illustrated in FIG. 9, the chip stack 11 may also be mounted on the wiring board 20 with the interposition of another semiconductor chip, such as an interface chip, a logic chip, or an interposer chip. It should be noted that FIG. 9 illustrates an example in which the chip stack 11 is mounted on the wiring board 20 with the interposition of a logic chip 80.

Further, in the descriptions in the first mode of embodiment to the third mode of embodiment, memory chips, in which memory circuits are formed, are used by way of example as the semiconductor chips 10 which form the chip stack 11, but the methods for manufacturing the semiconductor chips 10 illustrated in the first mode of embodiment to the third mode of embodiment may be applied to any type of semiconductor chip. For example, a semiconductor wafer on which are formed circuits used to realize the interface chips, logic chips, interposer chips and the like described above may be prepared, and after forming the modified layers 30 along the outer periphery of said chip regions, the semiconductor wafer may be cut and separated using a dicing blade.

Further, in the first mode of embodiment to the third mode of embodiment, a semiconductor device in which a chip stack 11 comprising a plurality (four) of semiconductor chips 10 is mounted on a wiring board 20 is shown by way of example, but the semiconductor device according to the present invention is not restricted to such a configuration. For example, the chip stack 11 may be formed from two, three or five or more semiconductor chips 10, and the semiconductor device may also have a configuration in which only one semiconductor chip 10 is mounted on a wiring board.

Further, the first mode of embodiment to the third mode of embodiment illustrate examples in which the modified layers 30 are formed reaching from the interior to the reverse surface of the semiconductor chip 10, but the modified layers 30 may for example be formed such that they reach from the reverse surface to the obverse surface of the semiconductor chip 10. In this case the amount of chipping that occurs over the entire side surface of the semiconductor chip 10 can be reduced.

### EXPLANATION OF THE REFERENCE NUMBERS

1, 2, 3, 4 Semiconductor device
10 Semiconductor chip
11 Chip stack
12₁ Obverse surface bump
12₂ Reverse surface bump
13 Through-electrode
14 First sealing resin layer
15 Wire bump
20 Wiring board
21 Connection pad
22 Metal ball
23 Land
24 Adhesive member
25 Second sealing resin layer
30 Modified layer
40 Semiconductor wafer
41 Semiconductor chip region
42 Cutting region
43 Insulating layer
44 Electrode pad
45, 48 Cu pillar
46 Ni plated layer
47 Au plated layer
49 Sn/Ag plated layer
50 Dicing tape
51 Tape base material
52 Adhesive layer
53 Condensing lens
54 Laser light
55 Dicing blade
60 Bonding tool
70 Insulating board
71 Product-forming portion
73 Insulating film
80 Logic chip
100 Bonding stage
130 Dispenser
131 Underfill

1. A semiconductor device comprising:
a wiring board, and
a semiconductor chip mounted on the wiring board, wherein the semiconductor chip comprises a modified layer which is formed along an outer periphery and which reaches at least from the interior to a surface on which a circuit is not formed.

2. The semiconductor device of claim 1, wherein the modified layer is an optically damaged portion.

3. The semiconductor device of claim 1, wherein the semiconductor chip comprises a bump electrode formed on the surface on which a circuit is not formed.

4. The semiconductor device of claim 1, comprising a plurality of the semiconductor chips, wherein at least one of the plurality of semiconductor chips is provided with a through-electrode and pad electrodes which are formed respectively on the one surface on which the circuits are formed, and on the other surface on which the circuits are not formed, and which are connected to the through-electrode, and the plurality of semiconductor chips are stacked on one other on the wiring board.

5. A method of manufacturing a semiconductor device, comprising:
preparing a semiconductor wafer having a plurality of semiconductor chip regions, on one surface of which desired circuits are formed, and cutting regions provided between the plurality of semiconductor chip regions;
forming modified layers in the semiconductor chip regions, along an outer periphery of said semiconductor chip regions, and reaching at least from the interior to another surface, on which the circuits are not formed; and
separating each of the plurality of semiconductor chip regions by cutting the semiconductor wafer in the cutting regions.

6. The method of claim 5, wherein the modified layers are formed by laser light irradiation.

7. The method of claim 5, wherein the cutting regions are cut using a dicing blade.

8. The method of claim 5, wherein a bump electrode is formed on the other surface of the semiconductor chip region.

9. A semiconductor chip comprising:
a circuit formed on one surface, and
a modified layer which is formed along an outer periphery and which reaches at least from the interior to another surface on which the circuit is not formed.

10. The semiconductor chip of claim 9, comprising a bump electrode formed on the other surface, on which a circuit is not formed.
